(19) United States
(12) Patent Application Publication
(10) Pub. No.: US 2008/0220585 A1
(43) Pub. Date: Sep. 11, 2008

(54) METHOD OF MANUFACTURING A SEMICONDUCTOR DEVICE

(75) Inventors: Takashi WATANABE, Kawasaki (JP); Seiichi SHIBATA, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 12/043,551

(22) Filed: Mar. 6, 2008

(30) Foreign Application Priority Data
Mar. 9, 2007 (JP) 2007-59417

(51) Int. Cl. H01L 21/762

(52) U.S. Cl. 438/424; 257/E21.545

(57) ABSTRACT

A method of manufacturing a semiconductor device comprises forming a silicon film, converting a surface of the silicon film into a hydrophilic surface, forming an insulating film over the silicon film, and polishing the insulating film formed over the silicon film.

### BACKGROUND

The present invention relates to a method of manufacturing a semiconductor device, and in particular, relates to a method of manufacturing a semiconductor device using a Chemical Mechanical Polishing (CMP) process.

In manufacturing semiconductor devices, it has been essential to perform planarization in the course of manufacture using a CMP process, in order to secure exposure margins for photolithography. For example, a CMP process has been used for planarization of an insulating film formed for a Shallow Trench Isolation (STI) structure or planarization of an insulating film formed over wiring or elements.

For example, an STI structure can be formed utilizing a CMP process, in accordance with a flow indicated in FIGS. 1A to 1D. FIG. 1A is a schematic cross-sectional view illustrating a principal part of a process of forming trenches for an STI structure. FIG. 1B is a schematic cross-sectional view illustrating a principal part of a process of forming an insulating film. FIG. 1C is a schematic cross-sectional view illustrating a CMP process. FIG. 1D is a schematic cross-sectional view illustrating an etching process.

A silicon oxide film 101 and a silicon nitride film 102 are formed in this order on a silicon substrate 100. Then, the silicon nitride film 102 and the silicon oxide film 101 are subjected to patterning to expose the silicon substrate 100. The exposed portions of the silicon substrate 100 are then etched to form trenches 103 as shown in FIG. 1A. As shown in FIG. 1B, a buried oxide film 104, for example a silicon oxide film, is formed over the entire surface to bury the trenches 103. Then, as shown in FIG. 1C, the buried oxide film 104 is polished for planarization using a CMP process until the silicon nitride film 102 is exposed. During the CMP process, the silicon nitride film 102 serves as a polish stop layer. As shown in FIG. 1D, the silicon nitride film 102 is removed by wet etching to form the STI structure made up of the buried oxide film 104.

After that, a gate electrode pattern is formed. Projected portions of the buried oxide film 104 shown in FIG. 1D, which portions remain after the removal of the silicon nitride film 102, will be removed by a wet process which is performed up until the formation of the gate electrode pattern. The gate electrode pattern is formed over a surface more planarized after the removal of the projected portions.

A first problem of a CMP process carried out in forming an STI structure is formation of recessed portions in the regions of the STI structure, which is a phenomenon so called “dishing.”

For example, when the STI structure is formed in accordance with the flow shown in FIGS. 1A to 1D, silicon oxide particles are generally used as abrasive grains. Also, the STI structure is generally formed under polishing conditions where the polishing speed of the buried oxide film 104 is higher than that of the silicon nitride film 102, or the polish stop layer. However, in the case of forming the STI structure having a relatively large area, polishing the buried oxide film 104 until the silicon nitride film 102 is exposed under the conditions where the polishing speed of the buried oxide film 104 is higher, will cause formation of the recessed portions in the buried oxide film 104 upon the completion of polishing. Formation of such recessed portions at the stage of forming the STI structure can cause defocusing in a lithography process that is performed at the later stages of forming a polysilicon film and forming the gate electrode pattern by patterning. This has raised a problem of allowing the width of the pattern to go out of a target value, or, depending on circumstances, of causing disconnection. Also, it has been a problem that such recessed portions may remain in the polysilicon film even after the formation of the gate electrode pattern.

An approach that can be taken for such a problem of dishing may be to arrange dummy active regions taking into account of an area so that the STI structure having a large area may not be arranged. If a polish stop layer, such as the silicon nitride film 102, is formed covering all the active regions including the dummy active regions, dishing may be suppressed from being caused when the buried oxide film 104 is polished. However, in the case where a dummy pattern is not arranged on purpose in order to prevent generation of parasitic capacity, or in the case where so-called dummy-inhibited regions are provided, dishing may likely be caused in the dummy-inhibited regions.

An another problem of the CMP process carried out in forming the STI structure is that, when polishing the buried oxide film 104 until the silicon nitride film 102 or the polish stop layer is exposed, the silicon nitride film 102 is also polished together with the buried oxide film 104.

If the silicon nitride film 102 is polished together with the buried oxide film 104 and the thickness of the silicon nitride film 102 is reduced, the thickness of each of the projected portions of the buried oxide film 104 remaining after the removal of the silicon nitride film 102 will be reduced. As mentioned above, these projected portions will be exposed by a wet process performed up until the formation of the gate electrode pattern. It may sometimes happen that wet process is carried out for the projected portions of the buried oxide film 104 in the state of their thickness having been reduced, on the assumption that such a reduction of the thickness of the film has not been caused. This has raised a problem of an excessive removal of the buried oxide film 104 and thus a problem of difficulty in obtaining a surface having good planarity at the stage of forming the gate electrode pattern.

In the case of performing a CMP process using cerium oxide particles, polishing proceeds while the cerium oxide particles react with the buried oxide film 104, so that a polishing speed ratio of the buried oxide film 104 to the silicon nitride film 102 can be made high. Carrying out polishing at such a polishing speed ratio may allow the buried oxide film 104 to be efficiently polished, and may suppress the reduction of the thickness of the silicon nitride film 102 while also suppressing dishing in the buried oxide film 104.

### SUMMARY

A method of manufacturing a semiconductor device according to an aspect of the present invention comprises forming a silicon film, converting a surface of the silicon film into a hydrophilic surface, forming an insulating film over the silicon film, and polishing the insulating film formed over the silicon film.

### BRIEF DESCRIPTION OF THE DRAWINGS

FIGS. 1A to 1D are schematic cross-sectional views each illustrating a process of forming an STI structure;

FIG. 2 is a schematic plan view illustrating a CMP device;

FIG. 3 is a schematic side view illustrating the CMP device;

FIGS. 4A and 4B are explanatory views each illustrating a CMP process;

FIG. 5 illustrates an example of another configuration of a polish stop layer;

FIG. 6 illustrates the results of measurement on an amount of reduction in the thickness of a polish stop layer; and

FIG. 7 illustrates the results of measurement on an amount of dishing in a buried oxide film.

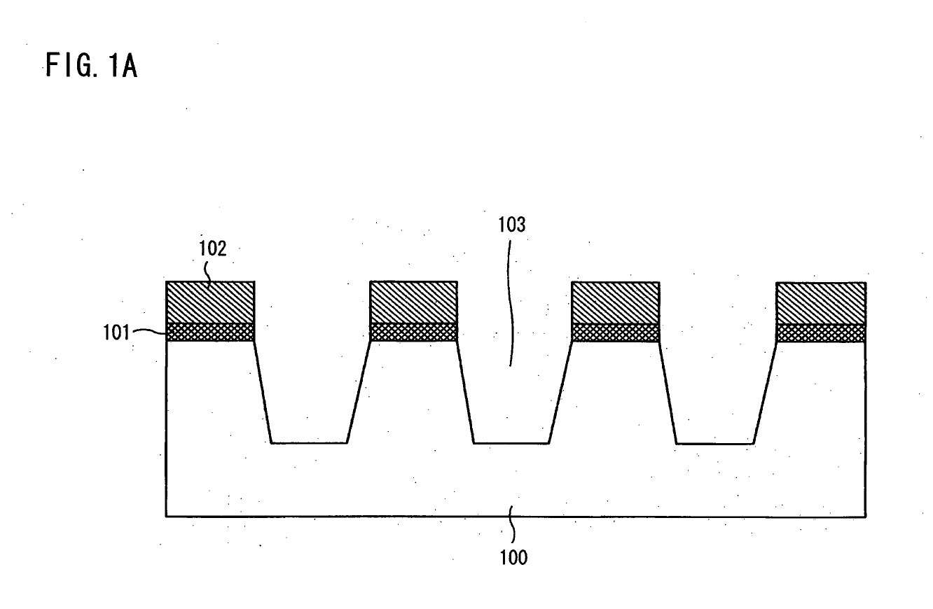

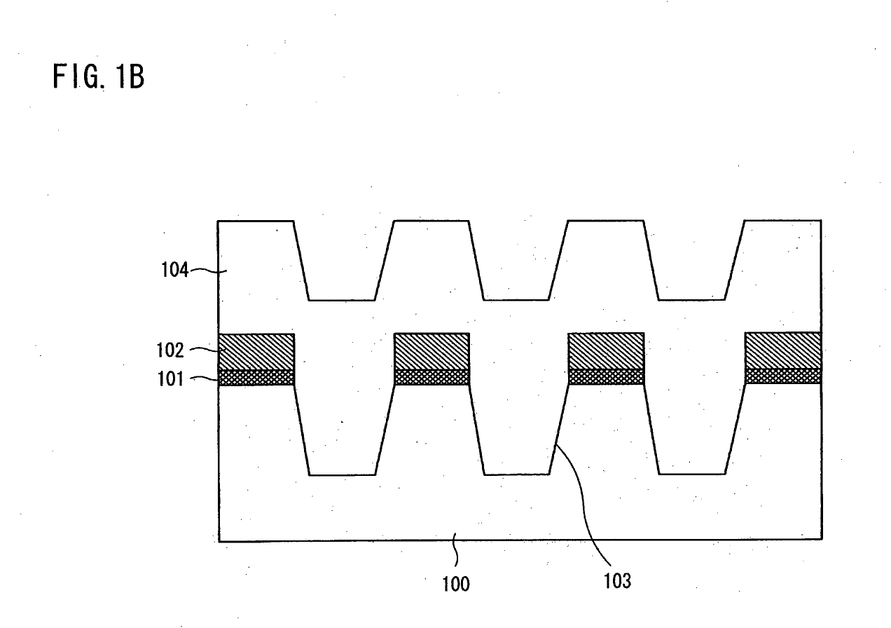

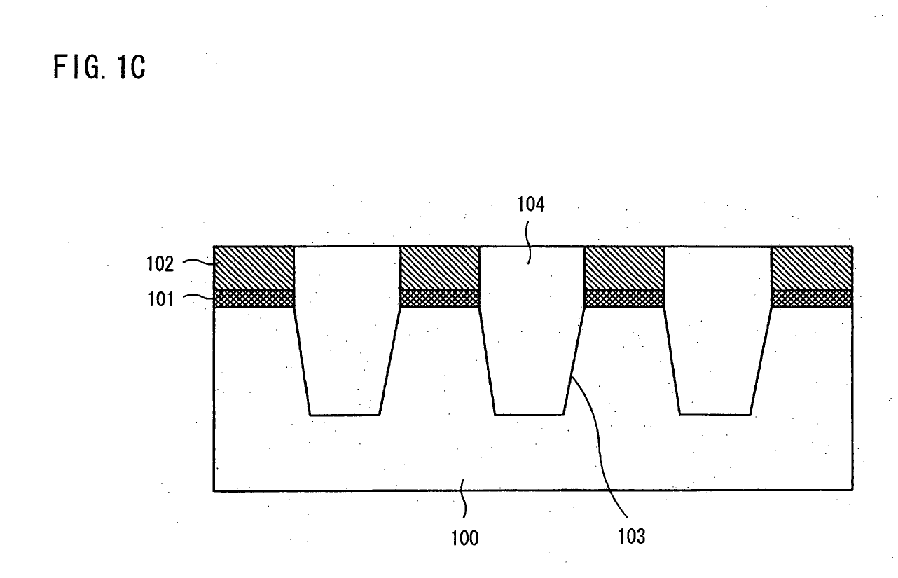

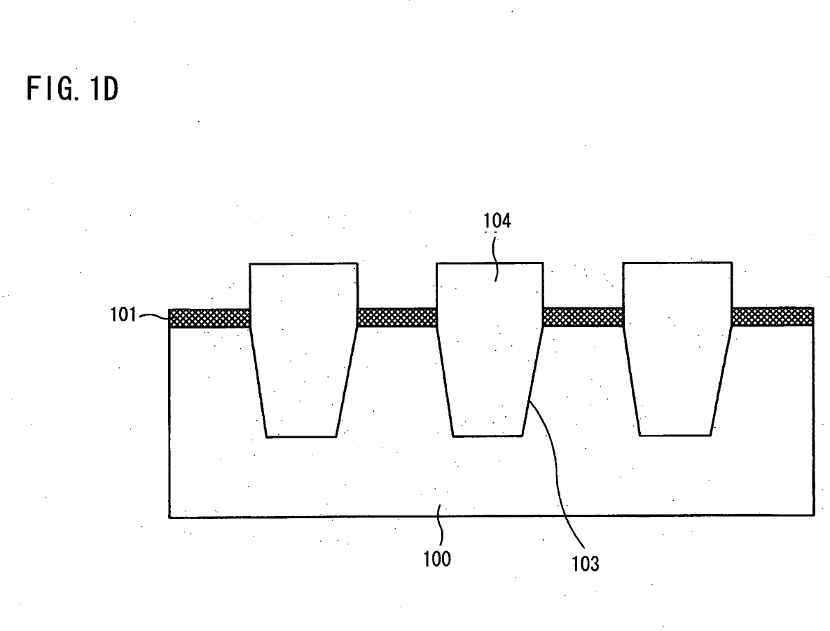

### DETAILED DESCRIPTION OF THE EMBODIMENTS

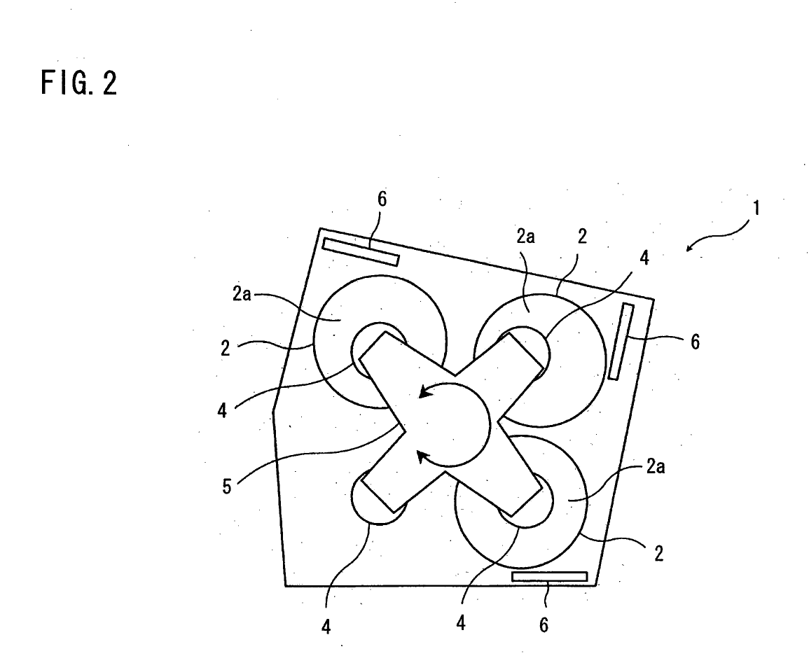

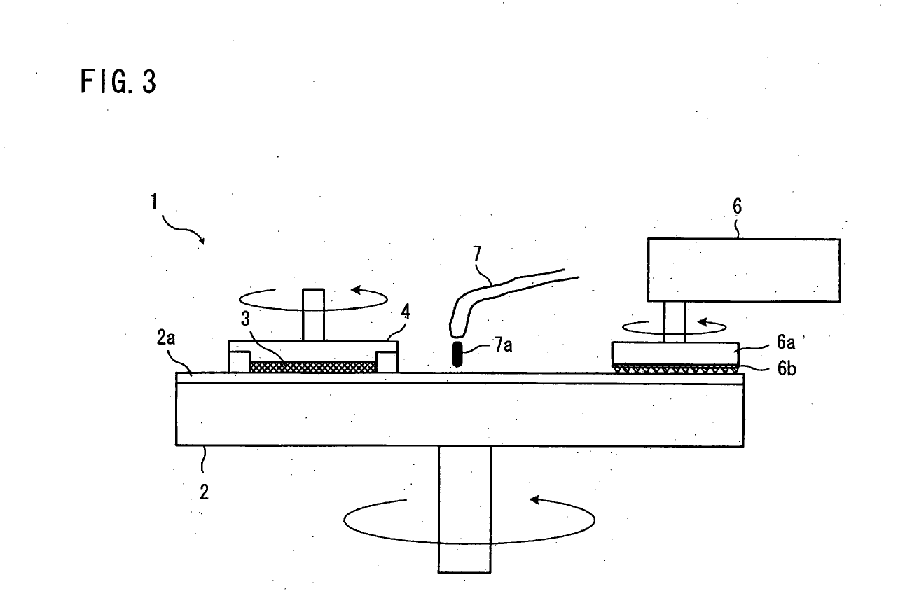

FIG. 2 is a schematic plan view illustrating a CMP device. FIG. 3 is a schematic side view illustrating a side view of the CMP device.

A CMP device 1 shown in FIGS. 2 and 3 includes polishing tables 2 each having a polishing pad 2a on the surface thereof, and polishing heads 4 each configured to enable holding of a wafer 3. FIG. 2 shows three polishing tables 2 and four polishing heads 4. FIG. 3 shows a portion including a set of the polishing table 2 and the polishing head 4.

The four polishing heads 4 of the CMP device 1 are attached to a rotatable support member 5. Each of the four polishing heads 4 is adapted to be movable toward each polishing table 2 with the rotation of the support member 5. Each of the polishing tables 2 is configured to be rotatable in a predetermined direction. Each of the polishing heads 4 is also configured to be rotatable in a predetermined direction.

Each of the polishing table 2 is provided with a dressing tool 6 for dressing the polishing pad 2a. As shown in FIG. 3, an end portion of the dressing tool 6 has a configuration in which a diamond disc 6b is attached onto a metal base 6a made for example, of stainless steel. The diamond disc 6b is structured by arranging several pieces of diamond in every 1 cm², each piece having a grain size of about 150 μm, and fixing them by Ni plating.

As shown in FIG. 3, the wafer 3 is polished by rotating the polishing table 2, and having the wafer 3 pressed onto the polishing pad 2a while the polishing head 4 holding the wafer 3 is rotated, with the supply of slurry 7a containing predetermined abrasive grains onto the polishing pad 2a from a slurry supply nozzle 7. The polishing pad 2a is dressed by the dressing tool 6 during intervals between the polishing performances of different wafers 3 or during a polishing performance of a single wafer 3.

Rotational speed or movement of each of the polishing tables 2, the polishing heads 4 and the support member 5 are controlled by driving current. The timing for finishing polishing of each wafer 3 is detected on the basis, for example, of a change of the drive current for rotating the polishing table 2 and the polishing head 4 at a constant speed.

Hereinafter is described a principle of polishing performed by using the CMP device 1 described above.

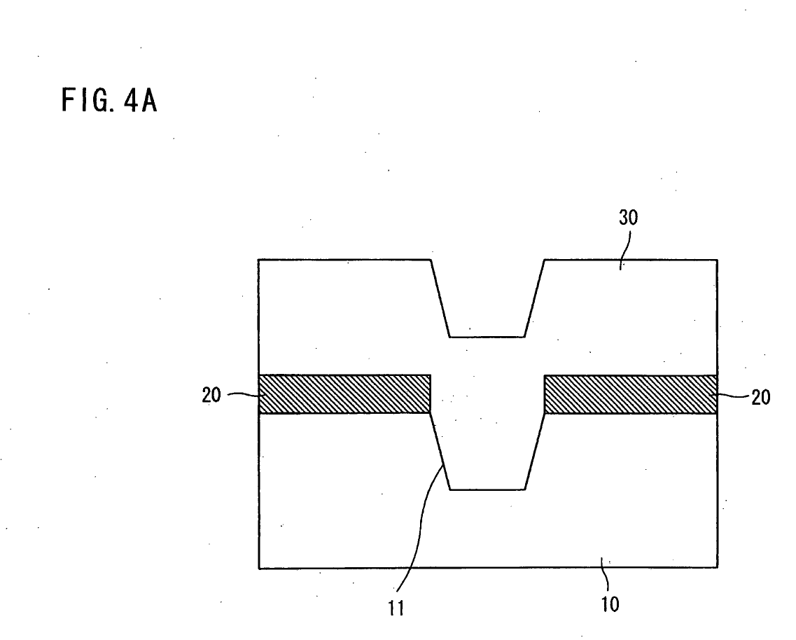

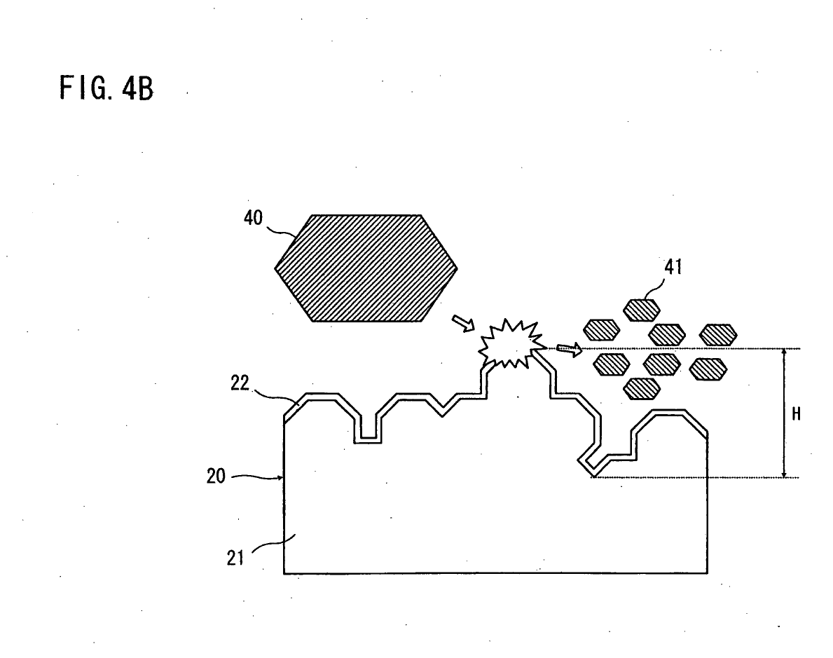

FIGS. 4A and 4B are explanatory views illustrating the principle of a CMP process. FIG. 4A shows that a polish stop layer 20 for stopping the CMP process is formed on a semiconductor substrate 10 and a buried oxide film 30 is formed to bury a trench 11 formed in the semiconductor substrate 10. This being the wafer 3 shown in FIG. 3, the buried oxide film 30 is polished using the CMP device 1 until the polish stop layer 20 is exposed. After that, by removing the polish stop layer 20, an STI structure is formed to provide element isolation regions.

FIG. 4B schematically illustrates a surface layer portion of the polish stop layer 20. As shown in FIG. 4B, the polish stop layer 20 has a rough film 21 having predetermined roughness and a hydrophilic surface film 22 formed on the surface of the film 21 along the roughness thereof.

The rough film 21 is formed, for example, of polysilicon and the surface film 22 is formed, for example, of silicon oxide or silicon nitride. In this case, the surface film 22 can be formed, for example, by forming the rough film 21 using polysilicon, followed by oxidizing a surface portion of the rough film 21 by thermal oxidization or the like, or nitriding a surface portion of the rough film 21 by having it reacted with ammonia or the like, for example. Alternatively, the surface film 22 may also be formed by forming the rough film 21, followed by depositing a film of silicon oxide or silicon nitride over the rough film 21, using a Chemical Vapor Deposition (CVD) process or the like.

The CMP process is thus performed for the buried oxide film 30 with the supply of the slurry 7a containing abrasive grains 40, with the use of the CMP device 1. In the course of the CMP process, when the polish stop layer 20 having roughness is exposed in the polishing surface, the abrasive grains 40 smash against the exposed portion of the polish stop layer 20. When the abrasive grains 40 are broken by the smash, abrasive grains 41 having smaller grain size are produced. Generally, as the size of an abrasive grain becomes smaller, polishing speed becomes lower. Accordingly, as the small abrasive grains 41 increase in the vicinity of the polish stop layer 20 exposed in the polishing surface with the occurrence of the breakage, the polishing speed in the involved region comes to be lower.

In this way, the occurrence of the breakage of the abrasive grains 40 after the polishing surface has reached the polish stop layer 20 during the CMP process, produces the small abrasive grains 41 which in turn lowers the polishing speed to thereby effectively suppress the thickness of the polish stop layer 20 from being reduced. In addition, such lowering of the polishing speed also reduces the polishing speed of the buried oxide film 30 in the vicinity of the polish stop layer 20. Accordingly, dishing caused in the buried oxide film 30 can also be effectively suppressed.

Preferably, the abrasive grains 40 are made of a material whose mechanical hardness is lower than that of at least the surface film 22, among the surface film 22 and the rough film 21 structuring the polish stop layer 20. This is because the fact that the mechanical hardness of the abrasive grains 40 is lower than that of the surface film 22 can cause efficient breakage of the abrasive grains 40 when they smash against the surface film 22. For the abrasive grains 40 that can satisfy such a mechanical hardness, cerium oxide particles are suitable, for example, in the case where the surface film 22 is formed of silicon oxide or silicon nitride.

The rough film 21 can be made either hydrophilic or hydrophobic. When the rough film 21 is made hydrophobic, as in the case of polysilicon, it is preferred that the CMP process is stopped before the surface film 22 is completely removed. Removal of the hydrophilic surface film 22 for the exposure of the rough hydrophobic film 21 thereunder is likely to raise a problem of allowing watermarks or foreign matter to remain when the wafer is washed after performing the CMP process. In order not to raise such a problem, it is preferred not to have the rough hydrophobic film 21 exposed in the surface after performing the CMP process. In structuring the polish stop layer 20, it is preferred that the surface of the polish stop layer 20 after the CMP process, is ensured to be hydrophilic. For example, it is preferred that a contact angle of each exposed portion of the polish stop layer 20 after the CMP process with respect to pure water is ensured to be 40 degrees or less. In the present specification, the case where the contact angle with respect to pure water is 40 degrees or less is defined as being hydrophilic, and the case where the contact angle with respect to pure water exceeds 40 degrees is defined as being hydrophobic.

Further, it is preferred that the CMP process is finished before the roughness of the polish stop layer 20 is planarized. This is because, if the roughness of the polish stop layer 20 is planarized, the abrasive grains 40 newly supplied thereto will not be broken and thus the lowering of the polishing speed will be suppressed, which in turn may not allow suppression of over-polishing. Preferably, the CMP process, which depends on polishing conditions, is performed under the conditions for allowing the maximum height H of the roughness of the polish stop layer 20 to be 3 nm or more at the time of finishing polishing. The polishing conditions are, for example, polishing speed, mechanical hardness of the abrasive grains 40 and 41, or the like.

Also, it is preferred that the maximum height H of the roughness of the polish stop layer 20 is smaller than the size of each abrasive grain 40 in use until the polishing is finished. This is because, if the maximum height H of the roughness of the polish stop layer 20 is larger than the size of each abrasive grain 40, the abrasive grain 40 is likely to be wholly caught by the recessed portion of the polish stop layer 20 to prevent the occurrence of efficient breakage. In the case of using cerium oxide particles as the abrasive grains 40, the maximum height H of the roughness of the polish stop layer 20 is preferably 50 nm or less, considering that the size of a cerium oxide particle generally used for the CMP process ranges from 50 nm to 200 nm.

In the case where the rough film 21 of the polish stop layer 20 is formed of polysilicon, the maximum height H of the roughness of the polish stop layer 20 will be about 5 nm or more since the grain size of polysilicon is about 10 nm. Conventionally, a polish stop layer has entirely been formed of silicon nitride, in which case the surface roughness of the silicon nitride film is about 2.7 nm, for example.

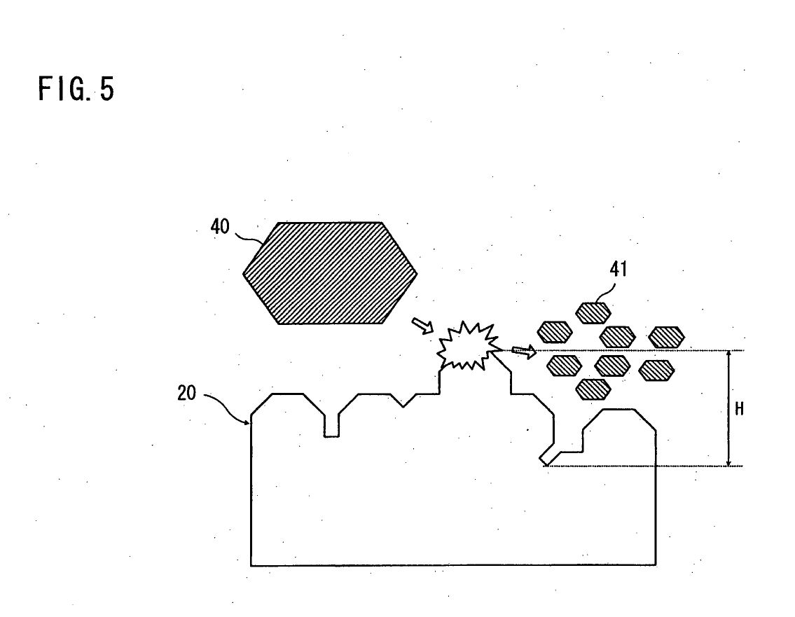

The polishing principle so far has been described referring to FIGS. 4A and 4B for the case where the polish stop layer 20 is structured by the rough film 21 and the surface film 22. Alternative to this structure, the polish stop layer 20 may be structured by a single layer as shown in the following FIG. 5.

FIG. 5 illustrates an example of another configuration of a polish stop layer.

A hydrophilic film having a rough surface as shown in FIG. 5 may be used solely as the polish stop layer 20. Such a polish stop layer 20 can be structured, for example, by forming a polysilicon film having a rough surface, and then subjecting the film to thermal oxidization or the like in its entirety to turn the film into a silicon oxide film. Alternatively, such a polish stop layer 20 may be structured by forming a polysilicon film having a rough surface, and then nitriding the entire film by, for example, having the film reacted with ammonia to turn the film into a silicon nitride film.

The polish stop layer 20 having the structure as shown in FIG. 5 may also allow the abrasive grains 40 to smash against the roughness of the polish stop layer 20 exposed in the polishing surface, whereby the small abrasive grains 41 are produced to thereby promote lowering of the polishing speed. Thus, the thickness of the polish stop layer 20 may be suppressed from being reduced, and in addition, dishing of the buried oxide film 30 in the vicinity of the polish stop layer 20 may also be suppressed from occurring.

Hereinafter will be specifically explained an Example to which the principle described above is applied.

First, a thermal oxide film of 10 nm thick was formed over a silicon substrate, followed by forming thereon a hydrophobic polysilicon film of 105 nm thick as a rough film. Observing the surface of the polysilicon film through an Atomic Force Microscope (AFM), the surface had been formed with roughness having a maximum height of 21 nm.

After thus forming the thermal oxide film and the polysilicon film over the silicon substrate, portions of the polysilicon film and the thermal oxide film residing in the regions for forming an STI structure were removed by lithography and etching, while forming trenches of 380 nm deep in these regions of the silicon substrate.

Subsequently, thermal oxidation process was performed at a temperature of 750° C. in a water vapor atmosphere to form a silicon oxide film of 4 nm thick as a surface film on the surfaces of the polysilicon film that had remained over the silicon substrate, so that the silicon oxide film will be provided along the roughness of the polysilicon film. In this way, a polish stop layer was formed, which consists of the polysilicon film and the silicon oxide film over the surface of the polysilicon film. The roughness observed on the surface of the polysilicon film before formation of the silicon oxide film was confirmed as being still maintained after formation of the silicon oxide film by the AMF after formation of the silicon oxide film.

In order to enhance the adhesiveness between a buried oxide film that will be described later and each trench, the thermal oxidation process involved the formation of thermal oxide film as a silicon oxide film over the surface of each trench formed in the silicon substrate, concurrently with the formation of the silicon oxide film on the surfaces of the polysilicon film.

The thickness of the silicon oxide film formed over the surface of the polysilicon film may be set, considering, for example, the material of the buried oxide film that will be described later and the conditions for carrying out the CMP process, as well as the time, for example, for forming the silicon oxide film over the surface of the polysilicon film. Formation of thinner silicon oxide film over the surface of the polysilicon film may allow the polishing surface to more readily reach the hydrophobic polysilicon film in the CMP process, which is more likely to cause some failure during wet washing performed after the CMP process, as described above. However, formation of such a thin silicon oxide film requires only a short-time thermal oxidation process. On the other hand, although the possibility of the occurrence of such failure may be reduced if a thick silicon oxide film is formed on the surface of the polysilicon film, formation of such a thick silicon oxide film may require the thermal oxidation process to be performed for a long time. When the time taken for the thermal oxidation process is considered, the silicon oxide film on the surface of the polysilicon film may preferably have a thickness of 15 nm or less.

It should be appreciated that the formation of the silicon oxide film over the surface of the polysilicon film may be performed before forming trenches in the silicon substrate. In this case, after forming a thermal oxide film over the silicon substrate, a polysilicon film is formed thereon as a rough film, which is followed by a predetermined thermal oxidation process to form a silicon oxide film as a surface film over the surface of the polysilicon film, so that the silicon oxide film will be provided along the roughness thereof. After that, portions of the silicon oxide film, the polysilicon film and the thermal oxide film residing in the regions for forming an STI structure are removed to form trenches in the silicon substrate.

Alternatively, formation of the silicon oxide film over the surface of the polysilicon film may be carried out during the process of forming the buried oxide film that will be described later. This alternative way of formation will be described later. After forming the polish stop layer, trenches and the like as described above, the buried oxide film having a thickness of 450 nm was formed using a High Density Plasma (HDP)-CVD process.

As described above, formation of the silicon oxide film over the surface of the polysilicon film can also be carried out during the process of forming the buried oxide film. In this case, a thermal oxide film and a polysilicon film are formed in this order over the silicon substrate first, followed by removing portions of the polysilicon film and the thermal oxide film residing in the regions for forming the STI structure, for formation of trenches in the silicon substrate. After that, the buried oxide film will be deposited using the HDP-CVD process. In this case, making use of a heat-up process for raising the temperature inside a chamber up to a deposition temperature of the buried oxide film , the surface of the polysilicon film is thermally oxidized before deposition of the buried oxide film. Then, when the temperature inside the chamber has reached a predetermined level, the deposition of the buried oxide film is started. Thus, a silicon oxide film can be formed over the surface of the polysilicon film, and at the same time, the trenches can be buried by the buried oxide film. It should be appreciated that the thermal oxide film over the surface of each of the trenches may be formed after forming the trenches and before proceeding to the deposition of the buried oxide film, or simultaneously with the thermal oxidation of the surface of the polysilicon film utilizing the heat-up process prior to the deposition of the buried oxide film.

After forming the buried oxide film, as shown in FIG. 3, the buried oxide film was subjected to polishing using the CMP device 1. As the polishing pad 2a, the IC1400 manufactured by Rodel Nitta Company was used.

The buried oxide film was polished by dividing the process into three steps. At the first polishing step, the buried oxide film was polished for 28 seconds, with the supply of the slurry 7a containing silicon oxide particles as the abrasive grains, onto the polishing pad 2a at a flow rate of 0.1 liter/min. Pressing force imposed on the polishing pad 2a of the wafer 3 was 20.7 kPa, the number of revolutions of the polishing head 4 was 102 rpm, and the number of revolutions of the polishing table 2 was 100 rpm. It should be appreciated that, at the time of finishing the first polishing step, the polish stop layer has not been exposed yet in the polishing surface.

At the second polishing step, the buried oxide film was polished for 12 seconds with the supply of the slurry 7a having hydrogen ion exponent (pH) of about 5 and containing cerium oxide particles as the abrasive grains, onto the polishing pad 2a at a flow rate of 0.135 liter/min. Pressing force was 27.6 kPa, the number of revolutions of the polishing head 4 was 142 rpm, and the number of revolutions of the polishing table 2 was 140 rpm. It should be appreciated that, at the time of finishing the second polishing step, the polish stop layer has not been exposed yet in the polishing surface.

At the third polishing step, the buried oxide film was polished with the supply of the slurry 7a having a pH of about 5 and containing Cerium oxide particles as the abrasive grains, onto the polishing pad 2a at a flow rate of 0.05 liter/min. and with the simultaneous supply of pure water onto the polishing pad 2a at a flow rate of 0.25 liter/min. Pressing force was 17.2 kPa, the number of revolutions of the polishing head 4 was 122 rpm, and the number of revolutions of the polishing table 2 was 120 rpm.

At the third polishing step, the buried oxide film was polished until the polish stop layer, for example the silicon oxide film, was exposed in the surface. The exposure of the polish stop layer was detected by detecting the drive current for rotating the polishing table 2. Although the materials of the polish stop layer and the buried oxide film are both silicon oxide, such a way of detecting the exposure of the polish stop layer is possible because the texture is different between the films. From the point of having detected the exposure of the polish stop layer, the entire buried oxide film was uniformly over-polished for 65 seconds without changing the conditions to put an end to the polishing of the buried oxide film. The conditions are, for example, conditions for supplying the slurry and the like, as well as pressing force and numbers of revolutions of the polishing head 4 and the polishing table 2.

Observation of the surface of the polish stop layer through an AFM after completion of the polishing revealed the presence of only fine roughness with a maximum height of 6 nm throughout the surface.

After completing polishing, the polish stop layer consisting of the silicon oxide film and the polysilicon film was removed by wet or dry etching, whereby the STI structure was formed with top ends being projected out of the silicon substrate.

The polishing conditions of the buried oxide film in the above Example have been given by way of example only, that is, polishing conditions should not be limited to those given in the above Example. Further, in the above Example, the polishing process was carried out by dividing the process into three steps. As a matter of course, however, the number of polishing steps should not be limited to three. Also, the exposure of the polish stop layer may be detected using an endpoint detector of light interference type, instead of detecting the drive current of rotation as described above.

The Example has so far been explained. Hereinafter will be explained the results of a research on the surface conditions after completing polishing in the above Example.

An explanation is given first on the results of a research on the hydrophilicity/hydrophobicity of the surface after completing polishing.

The following sample piece was prepared in order to research the hydrophilicity of the surface of the buried oxide film after completing polishing for the case where the buried oxide film was polished as in the Example explained above. First, a thermal oxide film of 10 nm thick and a polysilicon film as the rough film of 105 nm thick were formed in this order over a silicon substrate, followed by performing a thermal oxidation process at a temperature of 750° C. in a in a water vapor atmosphere to form a silicon oxide film as the hydrophilic film of 4 nm thick over the surface of the polysilicon film. Then, a silicon oxide film as the buried oxide film of 70 nm thick was formed using an HDP-CVD process.

For the sample piece prepared in this way, the silicon oxide film formed by using the HDP-CVD process was polished until the silicon oxide film formed by performing the thermal oxidation process of the surface of the polysilicon film was exposed, under the same conditions as in the third polishing step explained above. A contact angle between the polished surface and pure water was then measured. The contact angle between the surface and pure water was 20 degrees, and thus it was confirmed that the surface was hydrophilic.

An explanation is given on the results of the research on the reduction of the thickness of a polish stop layer and the dishing of a buried oxide film after completing polishing, for the case where the buried oxide film was polished as in the Example explained above.

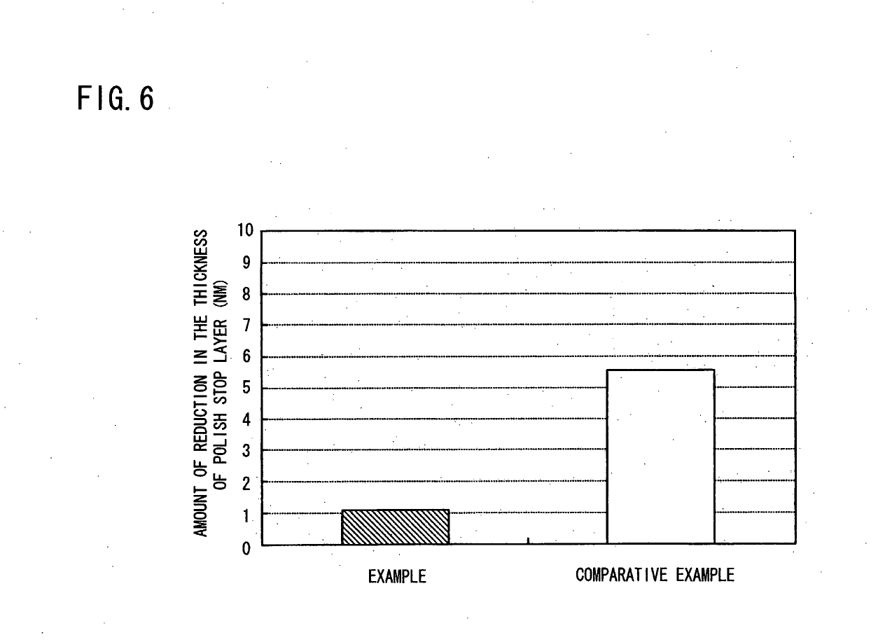

FIG. 6 shows the results of measurement of the amount of reduction in the thickness of the polish stop layer of the Example explained above after completing polishing of the buried oxide film. FIG. 6 also shows the results of measurement of the amount of reduction in the thickness of a polish stop layer of a sample piece prepared as a Comparative Example, which is entirely structured by a silicon nitride film.

The sample piece of the Comparative Example was prepared as follows. First, a thermal oxide film of 10 nm thick and a silicon nitride film of 105 nm thick were formed in this order over a silicon substrate, followed by lithography and dry etching to remove portions of the silicon nitride film and the thermal oxide film residing in the regions for forming STI structure, while forming trenches of 380 nm deep in these regions in the silicon substrate. Then, after performing thermal oxidation to form a thermal oxide film on the surface of each of the trenches, a buried oxide film of 450 nm thick was formed using the HDP-CVD process. For this sample piece of the Comparative Example, the buried oxide film was polished under the same conditions as in the Example explained above. After completing polishing, the amount of reduction in the thickness of the silicon nitride film, or the polish stop layer, was measured.

As can be seen from FIG. 6, reviewing the amount of reduction in the thickness of the polish stop layers of the Example and the Comparative Example, the amount of reduction in the thickness of the polish stop player of the Comparative Example was 5.5 nm, while that of the polish stop layer of the Example was 1.1 nm. This means that the amount of reduction of the latter was suppressed to ⅕ of the former. In the case of the Example, the polish stop layer is structured by forming the silicon oxide film of 4 nm thick over the surface of the polysilicon film of 105 nm thick. Since the amount of reduction in the thickness of the polish stop layer is 1.1 nm as shown in FIG. 6, polishing of the buried oxide layer can be regarded as having been finished in the state where the silicon oxide film over the surface of the polysilicon film has remained without being completely removed.

As can be seen from the results shown in FIG. 6, the amount of reduction in the thickness of the polish stop layer in the Example can be regarded as having been effectively suppressed during the polishing of the buried oxide film.

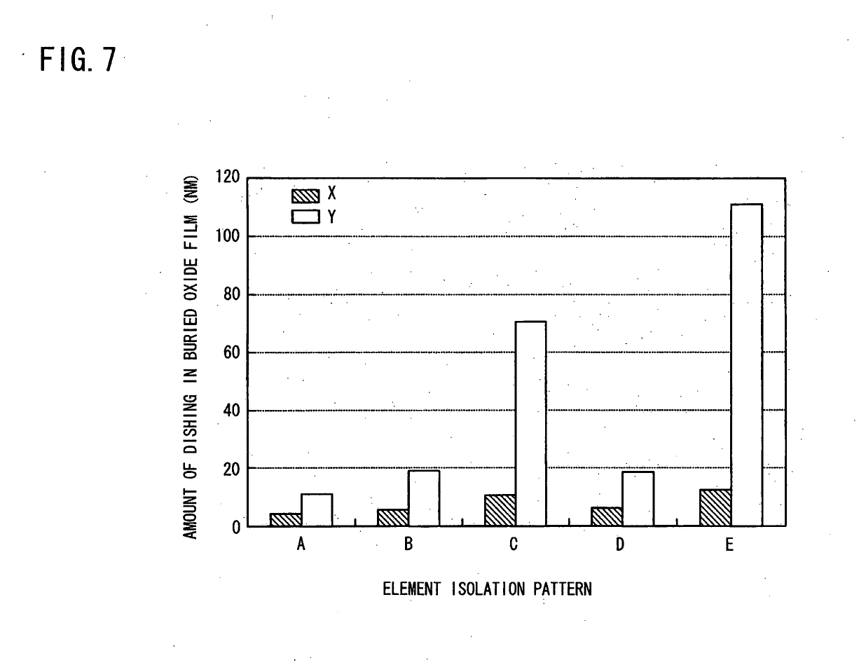

FIG. 7 shows the results of measurement on the amount of dishing in the buried oxide film.

In accordance with the Example explained above, five types of STI patterns A, B, C, D and E having different areas were formed here. In particular, a thermal oxide film and a polysilicon film were formed in this order over a silicon substrate as in the Example explained above. Then, five types of trenches having different areas were formed over the silicon substrate, followed by thermal oxidation to form a silicon oxide film over the surface of the polysilicon film, while forming a thermal oxide film over the surface of each trench. Then, a buried oxide film was finally formed using the HDP-CVD.

The buried oxide film was then polished as in the Example explained above to form the five types of STI patterns A, B, C, D and E of predetermined areas, followed by measuring the amount of dishing in the STI patterns.

For the sake of comparison, five types of STI patterns A, B, C, D and E of predetermined areas were also formed for the case where the entire polish stop layer was structured by a silicon nitride film, for measurement of the amount of dishing in these STI patterns. The sample piece in this case was prepared by forming five types of trenches having different areas, in accordance with the Comparative Example explained above.

FIG. 7 shows the results of measurement of the amount of dishing in the STI patterns A, B, C, D and E in the cases where the polish stop layer was structured by a polysilicon film and a silicon oxide film formed on the surface thereof X in the figure, and where the entire polish stop layer was structured by a silicon nitride film Y in the figure.

As can be seen from FIG. 7, in any of the STI patterns A, B, C, D and E, the amount of dishing in the buried oxide film was suppressed at a lower level in the case where the polish stop layer was structured by the polysilicon film and the silicon oxide film, than in the case where the entire polish stop layer was structured by the silicon nitride film.

Reviewing the results shown in FIG. 7, dishing during polishing of the buried oxide film can be regarded as having been effectively suppressed in the Example.

As described above, a film having roughness and a hydrophilic surface film formed over the surface thereof along the roughness are used as a polish stop layer for forming the STI structure using the CMP process. Alternatively, a hydrophilic film having roughness may be used as a polish stop layer. Thus, in polishing a buried oxide film for burying trenches, reduction in the thickness of the polish stop layer can be effectively suppressed, and in addition, dishing in the buried oxide film can be effectively suppressed. In this way, a surface having good planarity can be obtained after completing polishing. The surface with good planarity can also be obtained in the stage of forming a gate electrode pattern after performing the subsequent process of removing the polish stop layer and the wet process.

The Example has been explained, taking as an example the processes for forming a polysilicon film over a semiconductor substrate. Alternative to these processes, an amorphous silicon film may be formed over a semiconductor substrate, followed by heat treatment for crystallization to form a polysilicon film.

What is claimed is:

1. A method of manufacturing a semiconductor device comprising:
forming a silicon film over a semiconductor substrate;
patterning the silicon film;
forming a trench in the semiconductor substrate;
converting at least a surface of the silicon film into a hydrophilic surface;
forming an insulating film over the silicon film and in the trench; and
polishing the insulating film formed over the silicon film.

2. The method according to claim 1, wherein the silicon film is a polysilicon film.

3. The method according to claim 1, wherein converting the surface into the hydrophilic surface comprises, forming a silicon oxide film at least over the surface of the silicon film by thermally oxidizing the silicon film, or forming a silicon nitride film at least over the surface of the silicon film by having the silicon film reacted with ammonia.

4. The method according to claim 3, wherein polishing the insulating film is finished in a state where a surface of the silicon film after polishing shows hydrophilicity.

5. The method according to claim 2, wherein surface roughness of the silicon film after polishing is 3 nm or more.

6. The method according to claim 1, wherein polishing the insulating film is performed by using abrasive grains having a first mechanical hardness lower than a second mechanical hardness of the surface of the silicon film.

7. The method according to claim 6, wherein the abrasive grains are cerium oxide particles.

8. The method according to claim 1, wherein converting the surface into the hydrophilic surface is performed after forming the trench and before forming the insulating film.

9. The method according to claim 1, wherein converting the surface into the hydrophilic surface is forming a thermal oxide film over the surface of the silicon film in forming the insulating film.

10. The method according to claim 3, wherein the silicon oxide film has a thickness of 15 nm or less.

11. The method according to claim 1, wherein the silicon film is a film obtained by crystallizing an amorphous silicon layer formed over the semiconductor substrate by subjecting the amorphous silicon layer to heat treatment.

12. A method of manufacturing a semiconductor device comprising:
forming a polysilicon film over a semiconductor substrate;
patterning the polysilicon film;
forming a trench in the semiconductor substrate;
forming a silicon oxide film over a surface of the polysilicon film by performing heat treatment;
forming an insulating film over the polysilicon film and in the trench; and
polishing the insulating film formed over the polysilicon film using abrasive grains of cerium oxide.

13. The method according to claim 12, wherein surface roughness of the polysilicon film after polishing is 3 nm or more.

14. The method according to claim 12, wherein forming the silicon oxide film is performed after forming the trench and before forming the insulating film.

15. The method according to claim 12, wherein the silicon oxide film has a thickness of 15 nm or less.

16. The method according to claim 12, wherein the polysilicon film is a film obtained by crystallizing an amorphous silicon layer formed over the semiconductor substrate by subjecting the amorphous silicon layer to heat treatment.
